(19) United States
(12) Patent Application Publication
(10) Pub. No.: US 2011/0139236 A1
(43) Pub. Date: Jun. 16, 2011

(54) SOLAR CELL AND METHOD FOR MANUFACTURING THE SAME

(76) Inventors: Kyoungsoo LEE, (US); Jonghwan KIM, (US); Juwan KANG, (US); Manhyo HA, (US); Daehee JANG, (US)

(21) Appl. No.: 12/904,691

(22) Filed: Oct. 14, 2010

(30) Foreign Application Priority Data
Apr. 26, 2010 (KR) 10-2010-0038432

(51) Int. Cl. H01L 31/0236; H01L 31/18

(52) U.S. Cl. 136/256; 438/71; 257/E31.13

(57) ABSTRACT

A method for manufacturing a solar cell includes forming a textured surface at a surface of a substrate of a first conductivity type using a dry etching method, the textured surface having a plurality of jagged portions, forming a doping pattern by applying a doping material containing an impurity of a second conductivity type on a portion of the textured surface, forming an emitter region by doping the impurity of the second conductive type into the substrate to form a first emitter portion and a second emitter portion having a different impurity doped concentration from each other, forming an anti-reflection layer on the first emitter portion and the second emitter portion, and forming a first electrode connected to the second emitter portion and a second electrode connected to the substrate.

### CROSS-REFERENCE TO RELATED APPLICATION

This application claims priority to and the benefit of Korean Patent Application No. 10-2010-0038432 filed in the Korean Intellectual Property Office on Apr. 26, 2010, the entire contents of which are incorporated herein by reference.

### BACKGROUND OF THE INVENTION

1. Field of the Invention

Embodiments of the present invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted.

A solar cell generally includes a substrate and an emitter region, each of which is formed of a semiconductor, and a plurality of electrodes respectively connected to the substrate and the emitter region. The semiconductors forming the substrate and the emitter region have different conductive types, such as a p-type and an n-type. A p-n junction is formed at an interface between the substrate and the emitter region.

When light is incident on the solar cell, a plurality of electron-hole pairs are generated in the semiconductors. The electron-hole pairs are separated into electrons and holes by the photovoltaic effect. Thus, the separated electrons move to the n-type semiconductor (e.g., the emitter region) and the separated holes move to the p-type semiconductor (e.g., the substrate), The electrons and holes are respectively collected by the electrode electrically connected to the emitter region and the electrode electrically connected to the substrate. The electrodes are connected to one another using electric wires to thereby obtain electric power.

### SUMMARY OF THE INVENTION

According to an aspect of the present invention, a method for manufacturing a solar cell may include forming a textured surface at a surface of a substrate of a first conductivity type using a dry etching method, the textured surface having a plurality of jagged portions, forming a doping pattern by applying a doping material containing an impurity of a second conductivity type on a portion of the textured surface, forming an emitter region by doping the impurity of the second conductive type into the substrate to form a first emitter portion and a second emitter portion having a different impurity doped concentration from each other, forming an anti-reflection layer on the first emitter portion and the second emitter portion, and forming a first electrode connected to the second emitter portion and a second electrode connected to the substrate.

The first emitter portion may haves a sheet resistance of about 80 Ω/sq. to 150 Ω/sq. and the second emitter portion may have a sheet resistance of about 20 Ω/sq. to 70 Ω/sq.

The second emitter portion may be formed to correspond to a position of the doping pattern.

The doping material may include group IV nanoparticles.

The forming of the doping pattern may include coating a silicon ink containing the impurity of the second conductive type.

The coating of the silicon ink may be performed by at least one of an ink jet printing method, an aerosol-coating method and an electro-spray coating method.

The dry etching method may be a reaction ion etching method.

Each of the plurality of jagged portions may have a diameter and a height of about 300 nm to 800 nm.

According to another aspect of the present invention, a solar cell may include a substrate of a first conductive type and having a textured surface of a plurality of jagged portions, an emitter region positioned at the substrate, the emitter layer having a second conductive type opposite to the first conductivity type, a first emitter portion with a first impurity doped depth, and a second emitter portion with a second impurity doped depth greater than the first impurity doped depth, a first electrode connected to the second emitter portion, and a second electrode connected to the substrate, wherein each of the plurality of jagged portions has a diameter and a height of about 300 nm to 800 nm.

A distance from a surface of the substrate to a p-n junction portion of the first emitter region may be different from a distance from a surface of the substrate to a p-n junction portion of the second emitter region.

An impurity doped concentration of the first emitter portion may be less than that of the second emitter portion.

The impurity doped depth of the second emitter portion may include a varying impurity doped depth between the first impurity doped depth and the second impurity doped depth.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a perspective view of a solar cell according to an example embodiment of the invention;

FIG. 2 is a cross-sectional view taken along a line II-II of FIG. 1;

FIGS. 3A to 3F are sectional views sequentially showing processes for manufacturing a solar cell according to an example embodiment of the present invention; and

FIG. 4 shows examples of a second emitter region of a solar cell according to an example embodiment of the present invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to only the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Referring to the drawings, a solar cell and a method for manufacturing the solar cell according to an example embodiment of the present invention will be described.

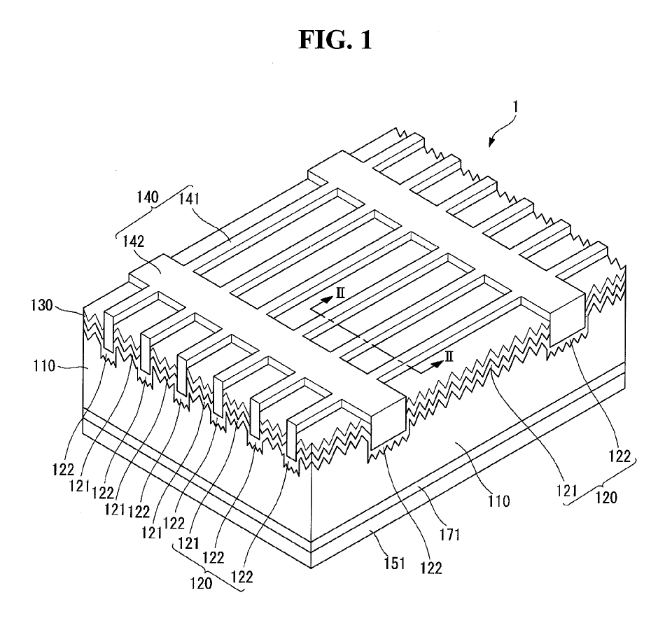

First, a solar cell according to an example embodiment of the present invention will be described in reference to FIGS. 1, 2 and 4.

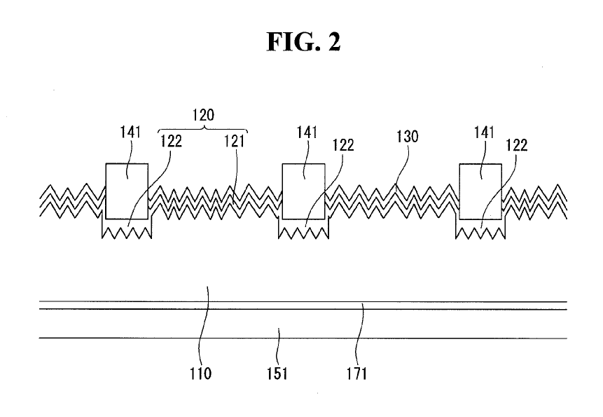

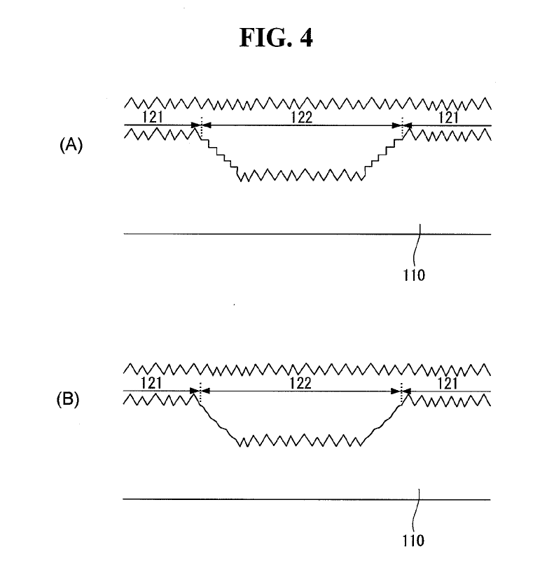

FIG. 1 is a perspective view of a solar cell according to an example embodiment of the invention and FIG. 2 is a cross-sectional view taken along a line II-II of FIG. 1. FIG. 4 shows other examples of a second emitter region of a solar cell according to an example embodiment of the present invention.

Referring to FIGS. 1 and 2, a solar cell 1 according to an example embodiment of the invention includes a substrate 110, an emitter region 120 positioned in (at) a surface (hereinafter, referred to as ‘a front surface’) of the substrate 110 on which light is incident, an anti-reflection layer 130 on the emitter region 120, a front electrode (a first electrode) 140 positioned at the front surface of the substrate 110 and connected to the emitter region 120, a rear electrode (a second electrode) 151 positioned on a surface (a rear surface) of the substrate 110, opposite the front surface of the substrate 110, on which the light is not incident, and connected to the substrate 110, and a back surface field (BSF) region 171 positioned between the substrate 110 and the rear electrode 151.

The substrate 110 is a semiconductor substrate formed of first conductive type silicon, for example, p-type silicon, though not required. In the embodiment, the silicon is polycrystalline silicon, but may be single crystal silicon in other embodiments. If the substrate 110 is of the p-type, the substrate 110 may contain a group III element impurity such as boron (B), gallium (Ga), and indium (In). Alternatively, the substrate 110 may be of an n-type. If the substrate 110 is of the n-type, the substrate 110 may contain a group V element impurity such as phosphorus (P), arsenic (As), and antimony (Sb). Alternatively, the substrate 110 may be materials other than silicon.

The front surface of the substrate 110 is textured to form a textured surface that is an uneven surface. Though somewhat exaggerated in FIGS. 1 and 2 for purposes of illustration, the texted surface includes a plurality of jagged portions as shown. Hence, a surface area of the substrate 110 increases and a light reflectance of the front surface of the substrate 110 is reduced. Accordingly, a light amount incident to the substrate 110 increases to improve an efficiency of the solar cell 1.

Each of the jagged portions may have a diameter (d2) (i.e., the maximum diameter) and a height (d1) of about 300 nm to 800 nm, and an aspect ratio (d2/d1)of each jagged portion may be about 1.0 to 1.5.

The emitter region 120 is an impurity region containing an impurity (e.g., an n-type impurity) of a second conductive type opposite the first conductive type of the substrate 110. The emitter region 120 is substantially positioned in (at) the entire front surface of the substrate 110, on which light is incident. The emitter region 120 forms a p-n junction with the substrate 110.

The emitter region 120 includes a first emitter portion 121 and a second emitter portion 122.

The first emitter portion 121 has a different impurity concentration (that is, an impurity doped concentration from that of the second emitter portion 122. For example, the impurity concentration of the second emitter portions 122 is heavier than that of the first emitter portion 121. In addition, an impurity doped depth of the second emitter portion 122 is greater than that of the first emitter portion 121, and thereby a thickness of the second emitter portion 122 is greater than that of first emitter portion 121. For example, the second emitter portion 122 has the thickness of about 400 nm to 700 nm from the surface of the substrate 110, and the first emitter portion 121 has a thickness of about 200 nm to 500 nm from the surface of the substrate 110.

Further, a distance (a first distance) from the surface of the substrate 110 to a p-n junction portion (a first junction portion) of the first emitter portion 121 and the substrate 110 and a distance (a second distance) from the surface of the substrate 110 to a p-n junction portion (a second junction portion) of the second emitter portion 122 and the substrate 110 are different from each other. That is, as shown in FIGS. 1 and 2, a vertical distance from the surface of the substrate 110 to the first junction portion is shorter than that from the surface of the substrate 110 to the second junction portion.

In this instance, regardless of a position difference due to a height difference between the jagged portions, and except for the boundary surface between the first emitter portion 121 and the second emitter portion 122, the first distance is substantially constant in the first emitter portion 121 and the second distance is substantially constant in the second emitter portion 122.

However, in an alternative embodiment, as shown in (A) and (B) of FIG. 4, the second distance in the second emitter portion 122 is not constant in every portion, but has a portion that gradually changes in parts of the p-n junction portion. That is, as shown in (A) of FIG. 4, the impurity doped depth (the second distance) of the second emitter portion 122 increases in phases (or steps) from the boundary surface with the first emitter portion 121, and then maintains the predetermined impurity doped depth. As shown in (B) of FIG. 4, the impurity doped depth (the second distance) of the second emitter portion 122 gradually increases from the boundary surface of the first emitter portion 121, and then maintains the predetermined impurity doped depth.

The sheet resistance of the first emitter portion 121 is more than that of the second emitter portion 122. For example, the first emitter portion 121 may have a sheet resistance of about 80 Ω/sq. to 150 Ω/sq. and the second emitter portion 122 may have a sheet resistance of about 20 Ω/sq. to 70Ω/q. In this instance, the first emitter portion 121 has the thickness less than that of an emitter portion formed in the substrate 110 according to a comparative example. Thereby, the first emitter portion 121 according to the embodiment has the sheet resistance mostly or generally greater than a sheet resistance (e.g., about 50Ω/sq. to 70Ω/sq.) of the emitter portion of the comparative example.

Since the emitter region 120 is formed by the impurity diffusion to (or doping) the substrate 110, the junction portion of the substrate 110 and the emitter portion 120 also has not a flat surface but an uneven surface under the influence of (or due to) the textured surface of the substrate 110.

By a built-in potential difference generated due to the p-n junction, a plurality of electron-hole pairs, which are generated by incident light onto the semiconductor substrate 110, are separated into electrons and holes, respectively, and the separated electrons move toward the n-type semiconductor and the separated holes move toward the p-type semiconductor. Thus, when the substrate 110 is of the p-type and the emitter region 120 is of the n-type, the separated holes move toward the substrate 110 and the separated electrons move toward the emitter region 120. Accordingly, the holes become major carriers in the substrate 110 and the electrons become major carriers in the emitter region 120.

Because the emitter region 120 forms the p-n junction with the substrate 110, when the substrate 110 is of the n-type, then the emitter region 120 is of the p-type, in contrast to the embodiment discussed above, and the separated electrons move toward the substrate 110 and the separated holes move toward the emitter region 120.

Returning to the embodiment of when the emitter region 120 is of the n-type, the emitter region 120 may be formed by doping the substrate 110 with the group V element impurity of such as P, As, Sb, etc., while when the emitter region 120 is of the p-type, the emitter region 120 may be formed by doping the substrate 110 with the group III element impurity such as B, Ga, In, etc.

In reference to FIGS. 1 and 2, the anti-reflection layer 130 positioned on the emitter region 120 is preferably, but not necessarily, made of hydrogenated- silicon nitride (SiNx:H) or hydrogenated silicon oxide (SiOx:H), etc. The anti-reflection layer 130 reduces reflectance of light incident onto the substrate 110 and increases selectivity of a specific wavelength band, thereby increasing efficiency of the solar cell 1. In this embodiment, the anti-reflection layer 130 has a single-layered structure, but the anti-reflection layer 130 may have a multi-layered structure such as a double-layered structure. The anti-reflection layer 130 may be omitted, if desired.

As shown in FIG. 1, the front electrode 140 includes a plurality of finger electrodes 141 and a plurality of bus bars 142.

The plurality of finger electrodes 141 are spaced apart from each other by a predetermined distance to be parallel to each other and extend in a direction on the second emitter portion 122 of the emitter region 120. The finger electrodes 141 are electrically and physically connected to the second emitter portion 122 of the emitter region 120. Accordingly, the second emitters 122 corresponding to the finger electrodes 141 and the second emitters 122 corresponding to the bus bars 142 cross each other.

The finger electrodes 141 collect charges, for example, electrons, moving toward the emitter region 120.

As shown in FIGS. 1 and 2, a width of each of the finger electrodes 141 is equal to or less than that of the underlying second emitter portion 122.

The plurality of bus bars 142 extend in a direction crossing the finger electrodes 141 along the second emitter portion 122 of the emitter region 120. The plurality of bus bars 142 are electrically and physically connected to the plurality of finger electrodes 141 as well as the second emitter portion 122 of the emitter region 120.

In this instance, the plurality of bus bars 142 are positioned on the same level layer as the finger electrodes 141 and are electrically and physically connected to the plurality of finger electrodes 141 at positions crossing each finger electrode 141.

Thereby, since the bus bars 142 are connected to the finger electrodes 141, the bus bars 142 collect the charges transferred through the finger electrodes 141 and output the charges to an external device.

Since each bus bar 142 has a width larger than that of each finger electrode 141, a width of a part of the second emitter portion 122 in contact with the bus bars 142 is larger than that a part of the second emitter portion 122 in contact with the finger electrodes 141.

In the embodiment, FIG. 1 shows two bus bars 142. However, the number of bus bars 142 may be changed. The width of each bus bar 142 may be also changed based on the number of bus bars 142.

As above-described, since the thickness of the first emitter portion 121 to which the front electrode 140 is not connected is less than that of the emitter region according to a comparative example, the impurity doped concentration of the first emitter portion 121 is also less than that of the emitter region according to the comparative example. Thereby, a flow of the charges moving through the first emitter portion 121 is improved, and thereby mobility of a charge moving towards the front electrode 140 through the second emitter portion 122 from the first emitter portion 121 is also improved and an amount of current from the solar cell 1 increases.

Further, as the thickness of the first emitter portion 121 decreases, the height of the p-n junction portion reduces to be closer to the surface of the substrate 110. That is, the vertical distance of the p-n junction portion from the surface of the substrate 110 decreases to reduce the distance between the front electrode 140 and the p-n junction portion. Thus, a moving distance of the charges to the front electrode 140 is reduced to increase a charge collection amount of the front electrode 140. Accordingly, the efficiency of the solar cell 1 is improved.

In addition, as compared to the emitter region of the comparative example, which does not include a plurality of different emitter portions, the second emitter portion 122 differing from the first emitter portion 121 contacts the front electrode 140 and including the plurality of finger electrodes 141 and the plurality of bus bars 142 has the low sheet resistance and the high conductivity due to the high impurity doped concentration. Thereby, in comparing to a case that the front electrode 140 is connected to the emitter region of the comparative example, a contact resistance between the front electrode 140 and the second emitter portion 122 is reduced, and thereby a transmission efficiency of the charges to the front electrode 140 increase to improve the efficiency of the solar cell 1.

The front electrodes 140 are preferably, but not necessarily, made of at least one conductive metal material such as silver (Ag). However, the conductive metal material may include at least one selected from the group consisting of nickel (Ni), copper (Cu), aluminum (Al), tin (Sn), zinc (Zn), indium (In), titanium (Ti), gold (Au), and a combination thereof. Other conductive metal materials may be used.

Due to the front electrode 140 being connected to the second emitter region 122 of the emitter region 120, the anti-reflection layer 130 is mainly positioned on the first emitter region 121 of the emitter region 120, on which the front electrode 140 is not positioned.

The rear electrode 151 is substantially positioned on the entire rear surface of the substrate 110.

The rear electrode 151 contains at least one conductive material such as aluminum (Al) and is connected to the substrate 110.

The rear electrode 151 collects charges, for example, holes, moving toward the substrate 110 and outputs the charges to the external device.

Alternatively, the rear electrode 151 may be made of a conductive material, and the conductive material may include at least one selected from the group consisting of Ni, Cu, Ag, Sn, Zn, In, Ti, Au, and a combination thereof. Other conductive materials may be used.

The back surface field region 171 positioned between the rear electrode 151 and the substrate 110 is an area more heavily doped with an impurity of the same conductive type as the substrate 120, and thereby, in this embodiment, the back surface field region 171 may be a p⁺-type area having an impurity doped concentration heavier than that of the substrate 110.

A potential barrier is formed by an impurity doped concentration difference between the substrate 110 and the back surface field region 171, thereby disrupting the movement of charges (for example, electrons) to a rear portion of the substrate 110. Accordingly, the back surface field region 171 prevents or reduces the recombination and/or the disappearance of the separated electrons and holes in the rear surface of the substrate 110.

The solar cell 1 may further include a plurality of bus bars (a plurality of rear electrode bus bars) for the rear electrode 151 positioned on the rear surface of the substrate 110.

Similar to the bus bars 141 of the front electrode 140, the plurality of rear electrode bus bars are electrically connected to the substrate 110 to collect the charges transferred from the rear electrode 151 and output the charges to the external device. The plurality of rear electrode bus bars are positioned to correspond to the bus bars 142 of the front electrode 140 and contain at least one conductive material such as silver (Ag).

An operation of the solar cell 1 of the structure will be described in detail.

When light irradiated to the solar cell 1 is incident on the substrate 110 of the semiconductor through the anti-reflection layer 130 and the emitter region 120, a plurality of electron-hole pairs are generated in the substrate 110 by light energy based on the incident light. In this instance, since a reflection loss of light incident onto the substrate 110 is reduced by the anti-reflection layer 130 and the textured surface of the substrate 110, an amount of the incident light on the substrate 110 increases.

The electron-hole pairs are separated by the p-n junction of the substrate 110 and the emitter region 120, and the separated electrons move toward the emitter region 120 of the n-type and the separated holes move toward the substrate 110 of the p-type. The electrons that move toward the emitter region 120 are mainly collected by the finger electrodes 141 and move along the bus bars 142, while the holes move toward the substrate 110 are collected by the rear electrode 151. When the bus bars 142 and the rear electrode 151 are connected to electric wires, current flows therein to thereby enable use of the current for electric power.

In this instance, since the first emitter portion 121, through which the charge movement toward the front electrode 140 is mainly performed, has high sheet resistance, the mobility of the charges improves, and since the second emitter portion 122 in contact with the front electrode 140 has a high impurity doped concentration and the low sheet resistance, a transmission efficiency of the charges to the front electrode 140 increases. Accordingly, the efficiency of the solar cell 1 is improved.

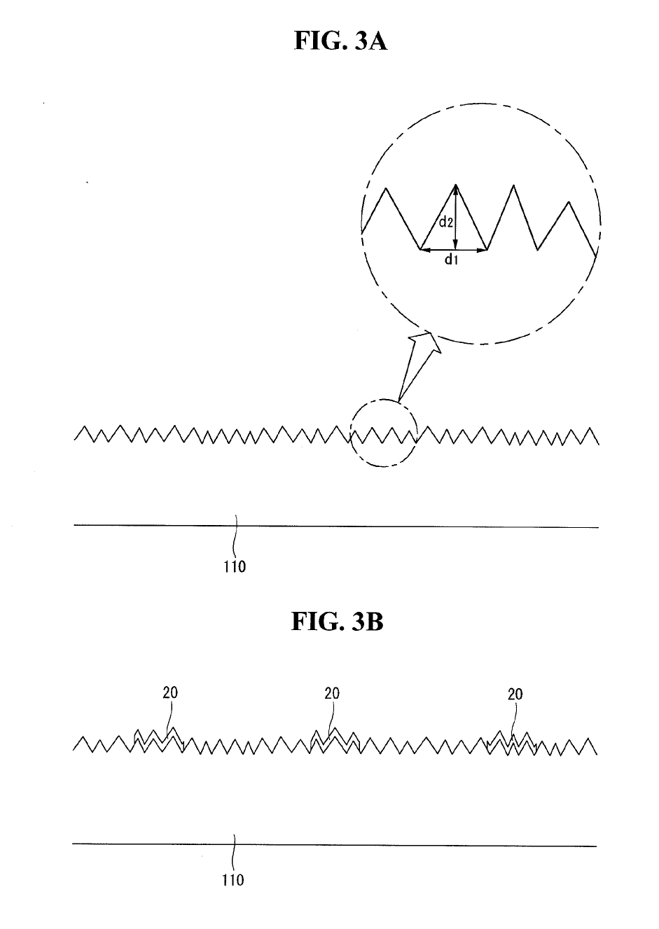

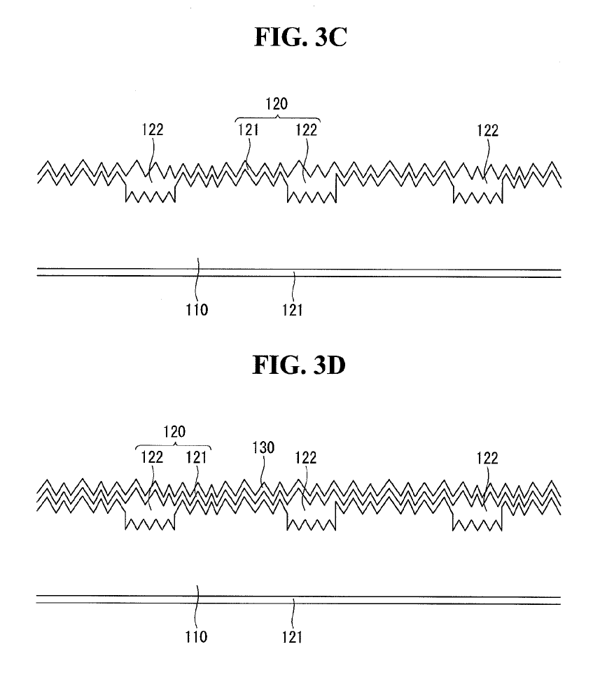

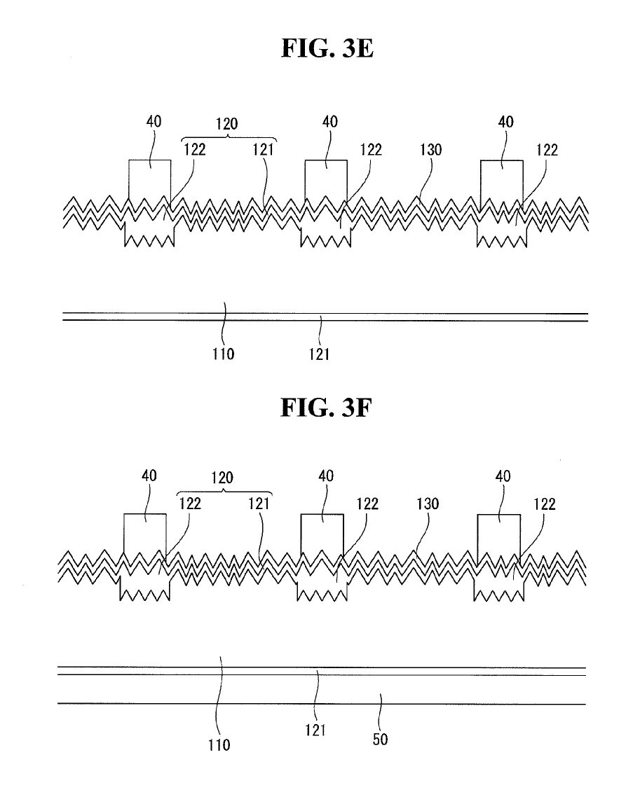

Next, referring to FIGS. 3A to 3F, discussed will be a method for manufacturing the solar cell 1 according to an example embodiment of the present invention.

FIGS. 3A to 3F are sectional views sequentially showing processes for manufacturing a solar cell according to an example embodiment of the present invention.

As shown in FIG. 3A, an exposed surface, for example, a front (incident) surface of a substrate 110 is etched using a dry etching method such as a reaction ion etching (RIE) method, etc., to form a textured surface having a plurality of jagged portions.

In this instance, the substrate 110 is made of p-type single crystal silicon, but the substrate 110 may be made of polycrystalline silicon or amorphous silicon of an n-type in other instances.

Each of the jagged portions has a diameter d1 and a height d2 of hundreds of nanometers, such as about 300 nm to 800 nm, respectively. In this instance, an aspect ratio (d2/d1) of each jagged portion may be about 1.0 to 1.5.

Since a size of each jagged portion is small, such as hundreds of nanometers and of a sub-micron size, a refractive index from the apex of each jagged portion to the substrate 110 is gradually changed. That is, an upper portion of the jagged portion has a refractive index similar to that of air, while a lower portion of the jagged portion has a refractive index similar to that of silicon (Si) contained in the substrate 110. Thus, in each jagged portion, generated is a layer stack effect obtained by stacked layers with different refractive index which are continuously changed.

Since the refractive index is changed according to the position change in each jagged portion by the layer stack effect, the wavelength of light absorbed into the substrate 110 also changed, and thereby the wavelength range of light absorbed into the substrate 110 also increases. Thus, by the textured surface of the embodiment, reflectance (for example, average weighted reflectance) of light in the wavelength range of about 300 nm to 1100 nm is about 10% or less. Accordingly, an anti-reflection efficiency of light increases to improve an efficiency of the solar cell 1.

Next, as shown in FIG. 3B, a doping material containing n-type impurities and group IV particles, and formed as an ink-type, is applied or coated on portions of the textured surface of the substrate 110 and then dried to form a doping pattern 20 on portions of the textured surface of the substrate 110. In the embodiment, the group IV particles are particles of a nanosize (in a width and/or a height), that is, group IV nanoparticles. In this instance, a nanoparticle refers to a microscopic particle with at least one dimension less than 100 nm. The term “group IV nanoparticle” generally refers to a hydrogen terminated group IV nanoparticle having an average diameter between about 1 nm to 100 nm. Thereby, the doping material of the doping pattern 20 may be group IV nanoparticles containing the n-type impurities.

In the embodiment, the group IV particles contain silicon (Si) which is the same material as the substrate 110, but the group IV particles may contain semiconductors other than silicon (Si) and/or a combination thereof.

In comparison to a bulk material (>100 nm) which tends to have constant physical properties regardless of its size (e.g., melting temperature, boiling temperature, density, conductivity, etc.), nanoparticles may have physical properties that are size dependent. Due to the physical properties that are size dependent, nonoparticles are useful for applications such as a junction. For example, semiconductor nanoparticles may be more easily and cheaply patterned into forming semiconductor junctions when compared to alternate methods, such as silk-screening or deposition.

Also, assembled nanoparticles may be suspended in a colloidal dispersion or a colloid, such as an ink, in order to transport and store the nanoparticles, for example, in a medium. Generally, colloidal dispersions of group IV nanoparticles are possible because the interaction of the particles surface with the solvent is strong enough to overcome differences in density, which usually result in a material either sinking or floating in a liquid. That is, smaller nanoparticles disperse more easily than larger nanoparticles. In general, the group IV nanoparticles are transferred into the colloidal dispersion under a vacuum, or an inert, substantially oxygen-free environment.

The doping pattern 20 containing the n-type impurities and the group IV nanoparticles may be formed by a direct printing method capable of directly printing or applying a desired material on desired portions, and such direct printing method includes an ink jet printing method, an aerosol-coating method, or an electro-spray coating method, etc.

Next, as shown in FIG. 3C, a high temperature thermal process involving a material (for example, POCl₃ or H₃PO₄) containing a group V element impurity such as P, As, or Sb is performed on the substrate 110 to diffuse (or dope) the group V element impurity into the substrate 110, thus forming an emitter region 120 which contains the impurity of the group V element. Hence, the emitter region 120 is formed at the surface of the substrate 110 including a front surface, a rear surface, and a side surface. Unlike the embodiment, when the substrate 110 is of the n-type, a high temperature thermal process involving a material (for example, B₂H₆) containing a group III element impurity is performed on the substrate 110 or the material containing the group III element impurity is formed on the substrate 110 to form a p-type emitter region at the surface of the substrate 110.

From the above description referring to FIG. 3B, since the doping pattern 20, that is, an ink 20 (silicon ink 20 in this instance) containing the n-type impurity, is already coated on the portions of the substrate 110, in the subsequent diffusing process at a high temperature of FIG. 3C, the impurity contained in the silicon ink 20 as well as the impurity contained in the POCl₃ or H₃PO₄ are driven (or doped) in the portions on the substrate 110 on which the silicon ink 20 are coated. In this instance, since the ink 20 contains silicon equal to the substrate 110, a chemical reaction between the silicon ink 20 and the substrate 110 is easily performed, whereby the diffusion operation of the impurities of the silicon ink 20 is easily performed. As described above, since the nanoparticles of the ink have a nano size, reactivity of the nanoparticles is good or improved. Thus, the diffusion operation of the phosphor (P) into the substrate 110 is also easily performed.

Thereby, an impurity doped concentration and an impurity doped depth in the portion of the substrate 110 on which the silicon ink 20 is coated are greater than that in the remaining portion of the substrate 110 on which the silicon ink 20 is not coated.

Accordingly, by diffusing the impurity contained in the POCl₃ or H₃PO₄ in portions of the substrate 110 on which the silicon ink 20 is not coated, as well as in portions of the substrate 110 on which the silicon ink 20 is coated, a first emitter portion 121 (of the emitter region 120) is formed in the portions of the substrate 110 on which the silicon ink 20 is not coated, and a second emitter portion 122 (of the emitter region 120) is formed in the portions of the substrate 100 on which the silicon ink 20 is coated. Thus, the impurity portion of the substrate 110 formed under the portion on which the silicon ink 20 is not coated functions as a first emitter portion 121 and the impurity portion of the substrate 110 formed under the portion on which the silicon ink 20 is coated functions as a second emitter portion 122, to form the emitter region 120 having the first and second emitter portions 121 and 122. Since the impurities are driven or doped from the surface of the substrate 110 into an internal portion of the substrate 110, a distance from the surface of the substrate 110 to a p-n junction portion of in first emitter portion 121 is different from a distance from the surface of the substrate 110 to a p-n junction portion of the second emitter portion 122, to generate a height difference between the p-n junction portions.

In the embodiment, the first emitter portion 121 may have a sheet resistance of about 80 Ω/sq. to 150 Ω/sq., and the second emitter portion 122 may have a sheet resistance of about 20 Ω/sq. to 700 Ω/sq.

As shown in FIG. 4, in an alternative embodiment, unlike FIG. 3C, an impurity doped depth of the second emitter portion 122 is changed, either gradually or in steps, from a boundary surface of the first emitter region 121 and the second emitter region 122 and then maintains a predetermined impurity doped depth.

In this embodiment, since the emitter region 120 (i.e., a selective emitter structure) including the first and second emitter portions 121 and 122 that have different impurity doped concentrations from each other is formed by the described method different from a wet etching method, the shape (i.e., the shape of the jagged portions) of the textured surface is not changed or a changed amount of the shape of the textured surface is reduced.

That is, when forming the selective emitter structure using the wet etching method, as it may be the case in a comparative example, first, an emitter region having a predetermined thickness (an impurity doped depth) is formed in (at) a textured substrate with a plurality of jagged portions by using a thermal diffusion method, etc. In this instance, the predetermined thickness is defined based on a predetermined low sheet resistance. Then, after forming an etch prevention mask on an etch undesired portion of the emitter region and/or the substrate for avoiding an undesired etching, the substrate is etched by the wet etching method using an etchant. Thereby, an exposed portion of the emitter region is etched, while the etch undesired portion of the emitter region, which is protected by the etching prevention mask, is not etched, to thereby form the selective emitter structure. That is, the portion of the emitter region, which is exposed to the etchant becomes a high sheet resistance portion and the portion of the emitter region, which is covered by the etch prevention mask becomes a low sheet resistance portion.

However, when performing the wet etching method, the controls of an etching direction and/or an etched thickness, etc., are difficult. Thereby, when the selective emitter structure is formed by the wet etching method, the thickness control of the high sheet resistance portion is not exactly or accurately performed and the etchant penetrates into the low sheet resistance portion, such that the sheet resistances (and the impurity doped depths) of the high sheet resistance portion and the low sheet resistance were not exactly (or accurately) and easily controlled. Further, an etched amount by the etchant was not constant and was varied according to a position of the jagged portion. For example, in each jagged portion, an etched amount near (at) the apex is greater than that near (at) the remaining portion (the periphery or the base), and thereby the shapes of the jagged portions of the textured surface were largely changed after the wet etching for the selective emitter structure. Thereby, since the shape of the textured surface that was designed for obtaining a low reflectivity was largely changed, the reflectivity of the textured surface increased after the formation of the selective emitter structure in such an instance.

However, in the embodiments of the invention, since the selective emitter structure is formed by the silicon ink 20 different from the wet etching method, the shape change of the textured surface is not generated after the formation of the selective emitter structure, unlike the wet etching method that causes the shape change of the textured surface. Thereby, the reflectivity of the textured surface of the embodiment is not increased. Further, by changing a coating state (e.g., a coated thickness or a coated size, etc.) of the silicon ink 20 and an amount of the impurity contained in the silicon ink 120, etc., the control of the sheet resistance is easily performed. Accordingly, after the formation of the selective emitter structure, the variation of the reflectivity does not occur and the characteristics of the emitter region 120 are easily controlled, and thereby the efficiency reduction of the solar cell 1 is reduced or prevented.

Further, since the emitter region 120 is not formed by the wet etching method that requires complicated processes, the processes for forming the selective emitter structure of the embodiment are eased and are simplified.

Subsequently, in FIG. 3C, phosphorous silicate glass (PSG) containing phosphor (P) or boron silicate glass (BSG) containing boron (B) produced when the p-type impurity or the n-type impurity is diffused into the substrate 110 is removed through an etching process. In addition, the impurity portion formed in the side surface of the substrate 110 by the diffusion of the impurity is removed by a laser beam or an etching. In this instance, the removing process of the impurity portion is called an edge isolation process. The timing of the edge isolation process may be changed, if it is necessary.

Next, as shown in FIG. 3D an anti-reflection layer 130 is formed on a portion of the emitter region 120 in the front surface of the substrate 110 using a plasma enhanced chemical vapor deposition (PECVD), etc.

Next, as shown in FIG. 3E, a front electrode paste containing Ag and glass frit is applied on corresponding portions of the anti-reflection layer 130 using a screen printing method and then is dried to form a front electrode pattern 40. The glass frit contains lead (Pb), etc.

In this instance, the front electrode pattern 40 includes a portion of a plurality of finger electrodes and a portion for a plurality of bus bars. The front electrode pattern 40 is formed on a position corresponding to the second emitter portion 122, and formed along the second emitter portion 122 on the anti-reflection layer 130.

Next, as shown in FIG. 3F, a rear electrode paste containing aluminum (Al) is applied on the rear surface of the substrate 110 using the screen printing method and then is dried, to form a rear electrode pattern 50 on the emitter region 120 formed at (in) the rear surface of the substrate 110.

In this instance, a temperature for drying the patterns 40 and 50 may be about 120° C. to 200° C. and a formation order of the front and back electrode patterns 40 and 50 may vary.

Next, a firing process is performed on the substrate 110, on which the front electrode pattern 40 and the rear electrode pattern 50 are formed at a temperature of about 750° C. to 800° C., to form a front electrode 140 including the plurality of finger electrodes 141 and the plurality of bus bars 142 that are connected to the second emitter portion 122 of the emitter region 120, a rear electrode 151 electrically connected to the substrate 110 and a back surface field region 171 between the substrate 110 and the rear electrode 151. As a result, the solar cell 1 shown in FIGS. 1 and 2 is completed.

More specifically, when the thermal process is performed, by functions of lead (Pb) etc., contained in the front electrode pattern 40, the front electrode pattern 40 etches (penetrates) through portions of the anti-reflection layer 130 underlying the front electrode pattern 40. Thereby, the front electrode pattern 40 is connected to the second emitter portion 122 of the emitter region 120 to form the front electrode 140 connected to the second emitter portion 122 of the emitter region 120.

In addition, during the thermal process, aluminum (Al) contained in the rear electrode pattern 50 is diffused (or doped) in the emitter region 120 formed at the rear surface of the substrate 110 to form an impurity region, that is, the back surface field region 171 that is highly doped with an impurity of the same conductive type as the substrate 110. In this instance, an impurity doped concentration of the back surface field region 171 is higher than that of the substrate 110.

The rear electrode pattern 50 is electrically connected to the substrate 110 through the back surface field region 171, to form the rear electrode 151.

Thereby, by an impurity doped concentration difference between the substrate 110 and the back surface field region 171, the back surface field region 171 prevents or reduces the recombination and/or the disappearance of the separated electrons and holes at the rear surface of the substrate 110 and helps the movement of the holes toward the rear electrode 151.

Moreover, in performing the thermal process, metal components contained in the patterns 40 and 50 are chemically coupled to the contacted emitter region 120 and the substrate 110, respectively, such that a contact resistance is reduced and thereby a transmission efficiency of the charges is improved to improve a current flow.

Furthermore, since the front electrode 140 is connected to the second emitter portion 122 with a higher impurity doped concentration and a lower sheet resistance than the first emitter portion 121, contact characteristics between the front electrode 140 and the second emitter portion 122 are improved.

In the embodiment, the emitter portion 121 formed in (at) the rear surface of the substrate 110 is not removed, but, in an alternative embodiment, before the formation of the rear electrode pattern 50, the emitter portion 121 formed in (at) the rear surface of the substrate 110 may be removed by a separate process.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a solar cell, the method comprising:
forming a textured surface at a surface of a substrate of a first conductivity type using a dry etching method, the textured surface having a plurality of jagged portions;
forming a doping pattern by applying a doping material containing an impurity of a second conductivity type on a portion of the textured surface;
forming an emitter region by doping the impurity of the second conductive type into the substrate to form a first emitter portion and a second emitter portion having a different impurity doped concentration from each other;
forming an anti-reflection layer on the first emitter portion and the second emitter portion; and
forming a first electrode connected to the second emitter portion and a second electrode connected to the substrate.

2. The method of claim 1, wherein the first emitter portion has a sheet resistance of about 80 Ω/sq. to 150 Ω/sq. and the second emitter portion has a sheet resistance of about 20 Ω/sq. to 70 Ω/sq.

3. The method of claim 2, wherein the second emitter portion is formed to correspond to a position of the doping pattern on the portion of the textured surface.

4. The method of claim 1, wherein the doping material comprises group IV nanoparticles.

5. The method of claim 1, wherein the forming of the doping pattern includes coating a silicon ink containing the impurity of the second conductive type.

6. The method of claim 5, wherein the coating of the silicon ink is performed by at least one of an ink-jet printing method, an aerosol-coating method and an electro-spray coating method.

7. The method of claim 1, wherein the dry etching method is a reaction ion etching method.

8. The method of claim 1, wherein each of the plurality of jagged portions has a diameter and a height of about 300 nm to 800 nm.

9. The method of claim 1, wherein the forming of the emitter region includes doping the impurity of the second conductive type into a portion of the textured surface on which the doping pattern was not formed to form the first emitter portion and doping the impurity of the second conductive type into the portion of the textured surface on which the doping pattern was formed to form the second emitter portion.

10. A solar cell, comprising:
a substrate of a first conductive type and having a textured surface of a plurality of jagged portions;
an emitter region positioned at the substrate, the emitter region having a second conductive type opposite to the first conductivity type, a first emitter portion with a first impurity doped depth, and a second emitter portion with a second impurity doped depth greater than the first impurity doped depth;
a first electrode connected to the second emitter portion; and
a second electrode connected to the substrate,
wherein each of the plurality of jagged portions has a diameter and a height of about 300 nm to 800 nm.

11. The solar cell of claim 10, wherein a distance from a surface of the substrate to a p-n junction portion of the first emitter region is different from a distance from the surface of the substrate to a p-n junction portion of the second emitter region.

12. The solar cell of claim 10, wherein an impurity doped concentration of the first emitter portion is less than an impurity doped concentration of the second emitter portion.

13. The solar cell of claim 10, wherein the second emitter portion further includes a varying impurity doped depth between the first impurity doped depth and the second impurity doped depth.

14. The solar cell of claim 13, wherein the varying impurity doped depth varies gradually over a predetermined distance in the second emitter portion.

15. The solar cell of claim 13, wherein the varying impurity doped depth varies in steps over a predetermined distance in the second emitter portion.

16. The solar cell of claim 10, wherein the first impurity doped depth and the second impurity doped depth are with respect to the textured surface.
